(19) United States
(12) Patent Application Publication
(10) Pub. No.: US 2026/0052748 A1
(43) Pub. Date: Feb. 19, 2026

(54) Gate Control Improvement of Semiconductor Devices and Methods of Forming Same

(71) Applicant: Taiwan Semiconductor Manufacturing Company, Ltd., Hsin-Chu (TW)

(72) Inventors: Chun-Fai CHENG, Tin Shui Wai (HK); Chang-Miao LIU, Hsinchu City (TW); Kuan-Chung CHEN, Taipei City (TW)

(21) Appl. No.: 18/808,286

(22) Filed: Aug. 19, 2024

(51) Int. Cl. H01L 29/66; H01L 21/3105; H01L 21/8234; H01L 27/088; H01L 29/06; H01L 29/08; H01L 29/423; H01L 29/775; H01L 29/786

(52) U.S. Cl. CPC H10D 64/017; H01L 21/31053; H10D 30/014; H10D 30/43; H10D 30/6735; H10D 30/6757; H10D 62/121; H10D 62/151; H10D 84/013; H10D 84/0135; H10D 84/038; H10D 84/83

(57) ABSTRACT

A method includes providing a workpiece. The workpiece includes a fin-shaped structure including a fin base and a stack of semiconductor layers over the fin base, a dummy gate structure disposed over the stack of semiconductor layers, and a source/drain feature connected to the channel layers of the stack of semiconductor layers and disposed on a side of the dummy gate structure. The stack of semiconductor layers includes channel layers interleaving with sacrificial layers. The method further includes forming a trench in the dummy gate structure and the fin-shaped structure, depositing a dielectric layer in the trench, depositing a polycrystalline semiconductor material over the dielectric layer, performing a planarization process to the workpiece, and replacing the dielectric layer, the polycrystalline semiconductor material, the dummy gate structure, and the sacrificial layers with a metal gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, short channel effect (SCE) and reduced gate-all-around behavior (e.g., controllability by the gate) may have impacts on the overall performance of an IC device. While existing techniques are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 4, 5, 6, 7, 8, 9, 10, 11A, 11B, 12, 13A, 13B, 14, 15, 16, 17, 18A, and 18B illustrate fragmentary cross-sectional views of an exemplary semiconductor structure during various fabrication stages in the method of FIG. 1, according to one or more aspects of the present disclosure.

FIG. 19 illustrates a fragmentary top view of an exemplary semiconductor structure, according to one or more aspects of the present disclosure.

FIGS. 20A and 20B illustrate fragmentary cross-sectional views of the semiconductor structure taken along line C-C′ and D-D′ as shown in FIG. 19, respectively, according to one or more aspects of the present disclosure.

FIG. 21 illustrates a flowchart of a method for forming a semiconductor structure, according to one or more aspects of the present disclosure.

FIGS. 22, 26, 31, and 35 illustrate fragmentary top views of an exemplary semiconductor structure during various fabrication stages in the method of FIG. 21, according to one or more aspects of the present disclosure.

FIGS. 23, 24, 25, 27, 28, 29, 30, 32, 33, 34, 36, 37A, 37B, and 38 illustrate fragmentary cross-sectional views of the semiconductor structure during various fabrication stages in the method of FIG. 21, according to one or more aspects of the present disclosure.

FIG. 39 illustrates a fragmentary top view of an exemplary semiconductor structure, according to one or more aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor. SCE may increase and gate-all around behavior may be reduced as widths of the channel regions increase, which may impact the overall performance of a multi-gate device. While existing techniques are generally adequate for their intended purposes, they are not satisfactory in all aspects.

The present disclosure provides various embodiments of a semiconductor structure. Particularly, the semiconductor structure includes a multi-gate device, such as a GAA transistor or a FinFET transistor. The semiconductor structure includes an active region or a combined active region including a channel region and a source/drain region, a gate structure disposed over the channel region, and a source/drain feature disposed in the source/drain region. The channel region may include two or more stacks of channel layers. The gate structure wraps around the channel layers and is disposed between neighboring stacks of channel layers. The source/drain feature is connected to the two or more stacks of channel layers and may include multiple epitaxial layers. In some embodiments, the combined active region includes two or more fin-shaped structures, and the source/drain feature is a merged source/drain feature and is disposed over two or more base fin structures of the two or more fin-shaped structures. In some other embodiments, the source/drain feature is disposed over a single base fin structure of the active region. By having two or more stacks of channel layers wrapped around by the gate structure and connected to the shared source/drain feature, while having a relatively large total channel width, gate control of the channel layers may be improved, short channel effect and sheet-width loading effect may be reduced, and process window of gate replacement and metal gate patterning may be increased.

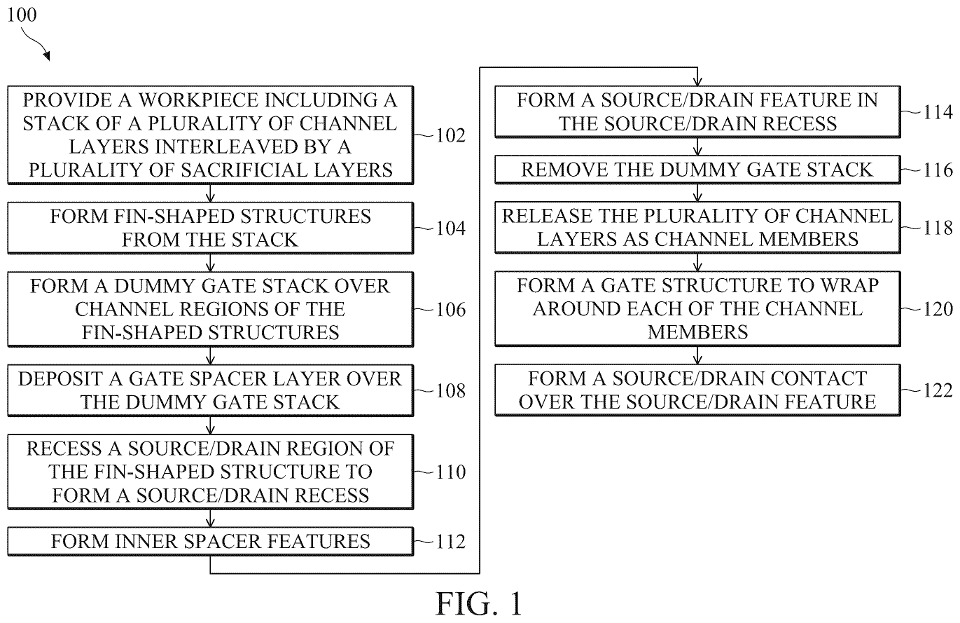

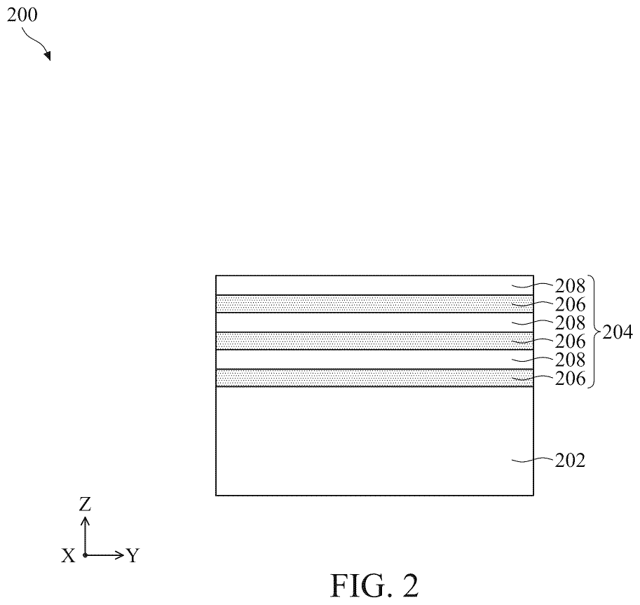

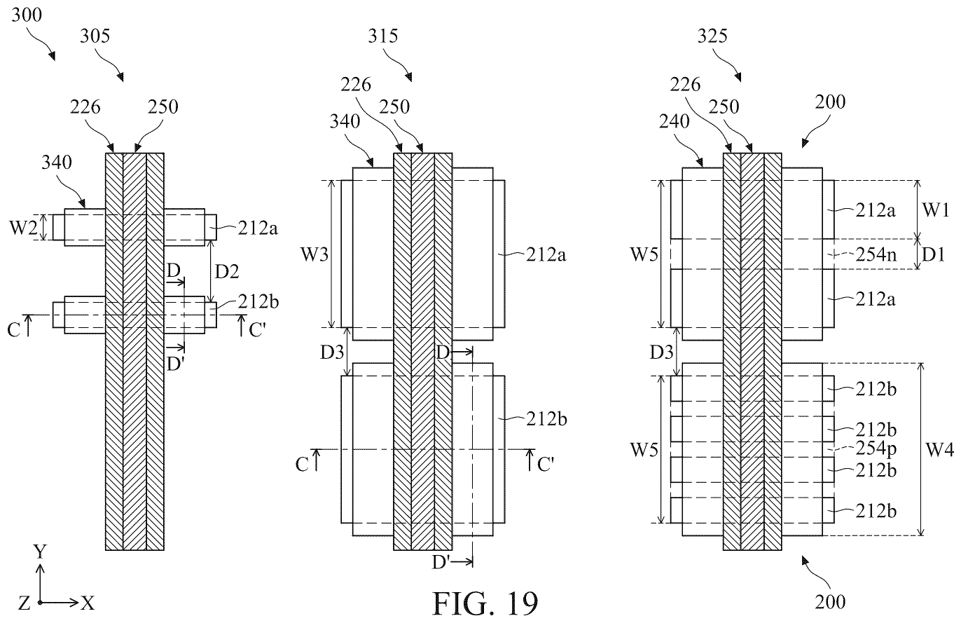

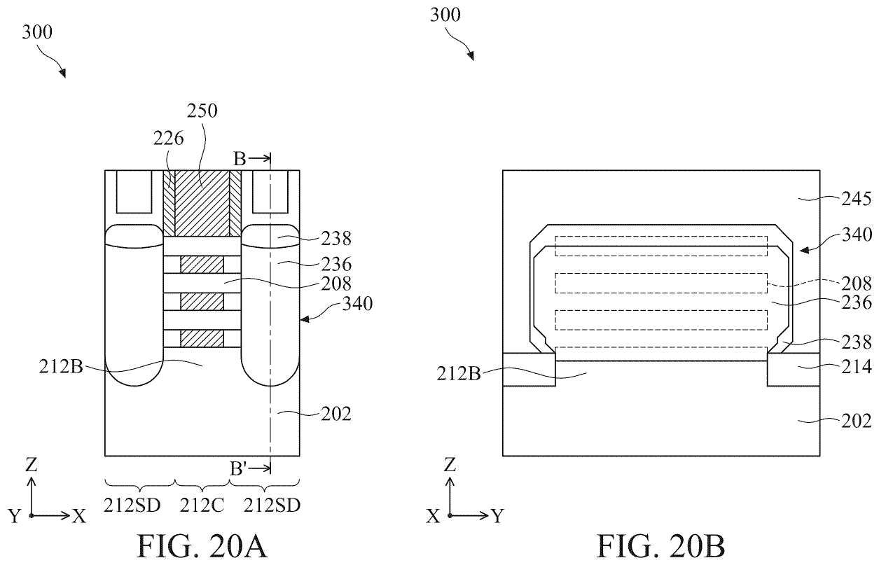

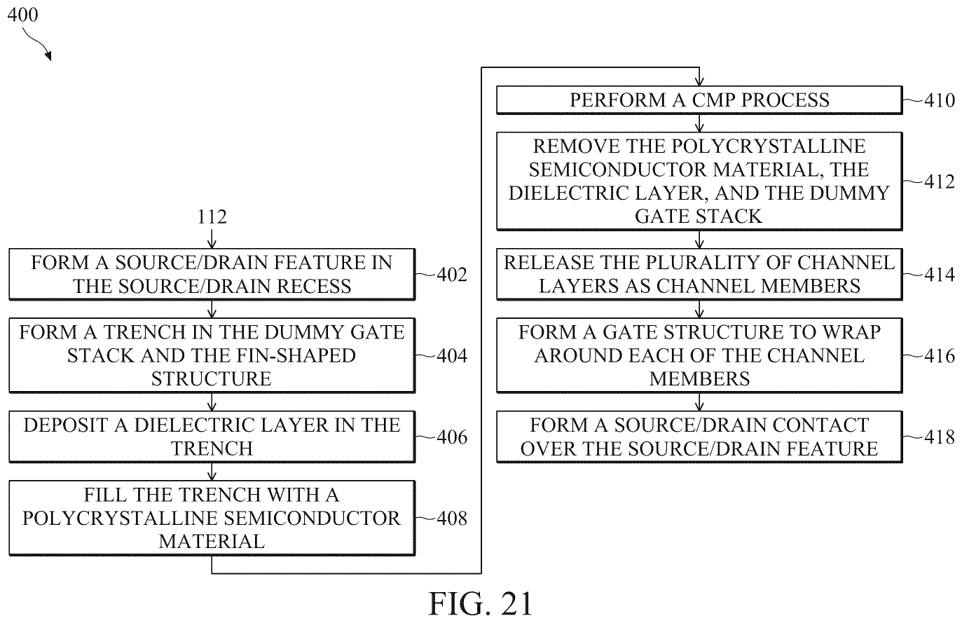

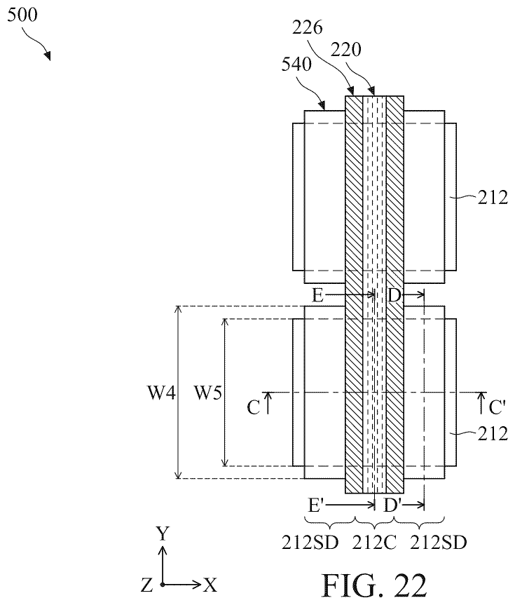

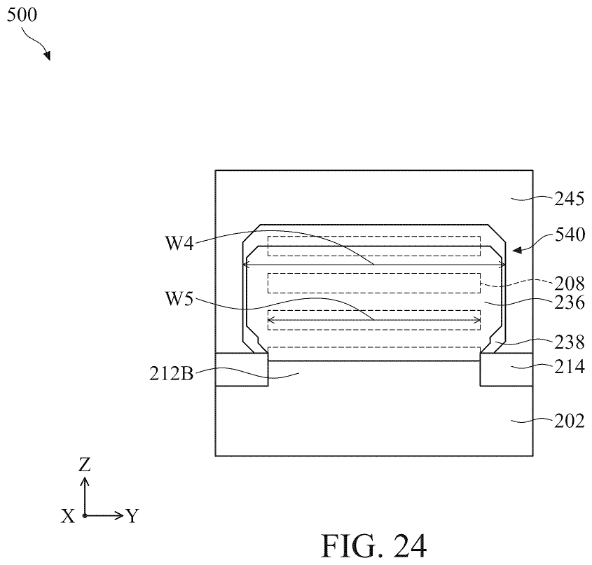

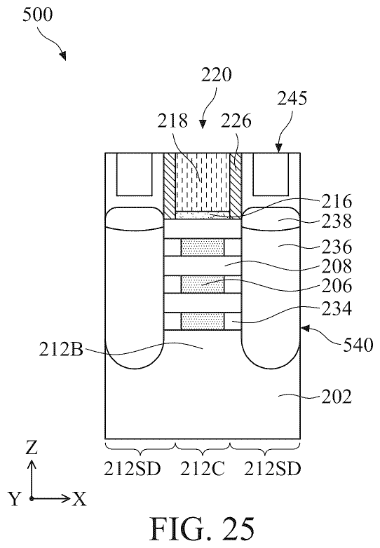

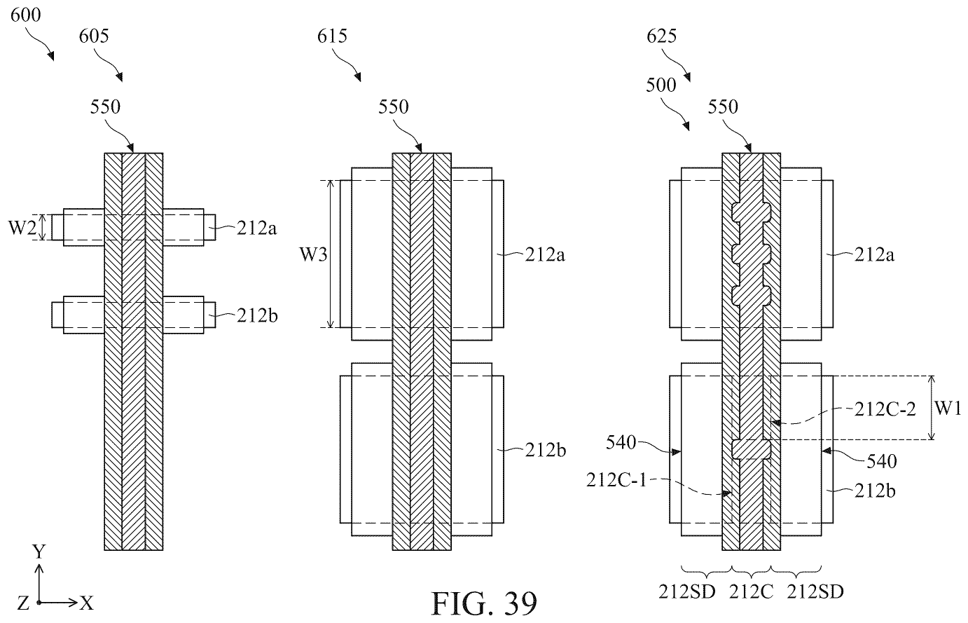

The various aspects of the present disclosure will now be described in more detail with reference to the figures. In that regard, FIG. 1 is a flowchart illustrating method 100 of forming a semiconductor structure according to embodiments of the present disclosure. FIG. 21 is a flowchart illustrating method 400 of forming an alternative semiconductor structure according to embodiments of the present disclosure. Methods 100 and 400 are merely examples and are not intended to limit the present disclosure to what is explicitly illustrated in method 100 and 400. Additional steps can be provided before, during and after method 100 and/or 400, and some steps described can be replaced, eliminated, or moved around for additional embodiments of the method. Not all steps are described herein in detail for reasons of simplicity. Method 100 is described below in conjunction with FIGS. 2-18B, which are fragmentary cross-sectional views of a workpiece 200 at different stages of fabrication according to embodiments of method 100 in FIG. 1. Method 400 is described below in conjunction with FIGS. 22-38, which are fragmentary top/cross-sectional views of an alternative workpiece 500 at different stages of fabrication according to embodiments of the method 400 in FIG. 21. Because the workpiece 200 (or 500) will be fabricated into a semiconductor structure or a semiconductor device, the workpiece 200 (or 500) may be referred to herein as a semiconductor structure 200 (or 500) or a semiconductor device 200 (or 500) as the context requires. FIGS. 19-20B illustrate fragmentary top/cross-sectional views of an exemplary semiconductor structure 300, according to one or more aspects of the present disclosure. FIG. 39 illustrates a fragmentary top view of an exemplary semiconductor structure 600, according to one or more aspects of the present disclosure. For avoidance of doubts, the X, Y and Z directions in FIGS. 2-20B and 22-39 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including additional transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 2, method 100 includes a block 102 where a workpiece 200 is provided. As shown in FIG. 2, the workpiece 200 includes a substrate 202 and a stack 204 of alternating semiconductor layers is formed over the workpiece 200. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

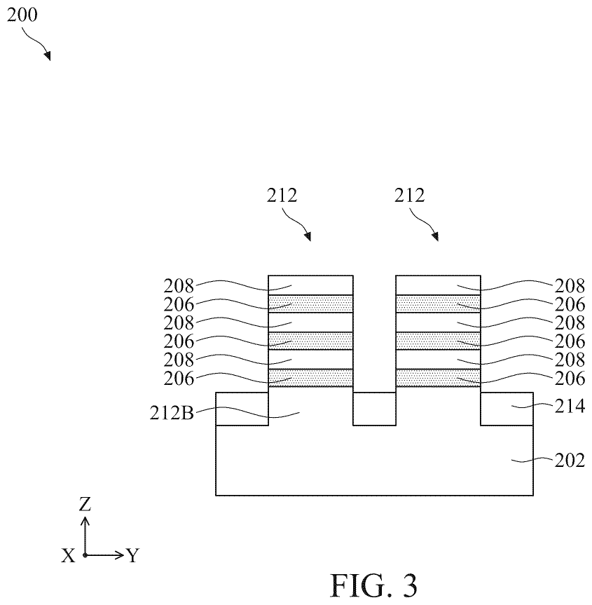

Referring to FIGS. 1 and 3, method 100 includes a block 104 where a fin-shaped structure 212 (also referred to as an active region 212) is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

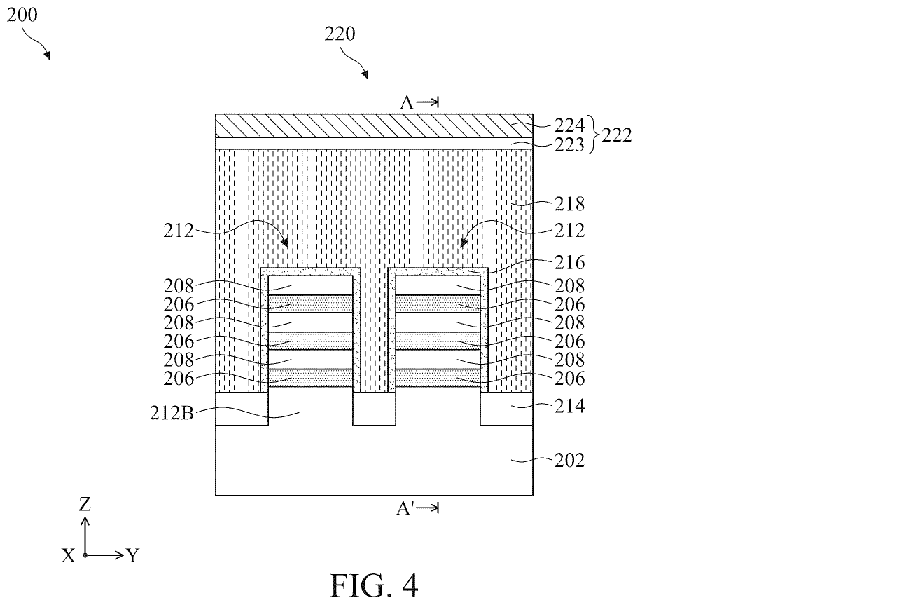

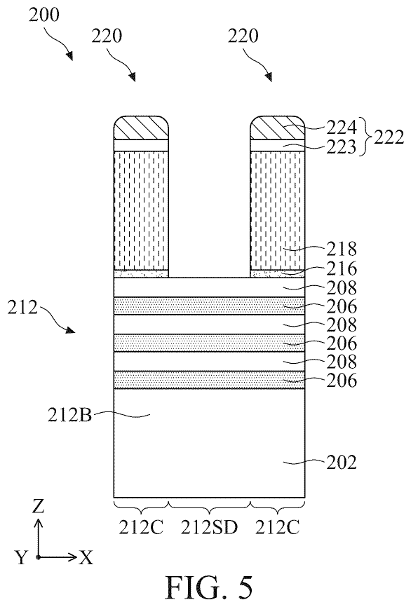

Referring to FIGS. 1, 4 and 5, method 100 includes a block 106 where a dummy gate stack 220 is formed over a channel region 212C of the fin-shaped structure 212. FIG. 5 illustrates a fragmentary cross-section view of the workpiece 200 taken along line A-A′ as in FIG. 4. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

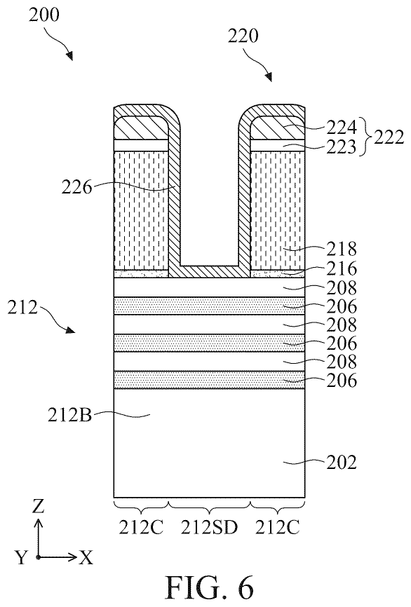

Referring to FIGS. 1 and 6, method 100 includes a block 108 where a gate spacer layer 226 is deposited over the workpiece 200, including over the dummy gate stack 220. In some embodiments, the gate spacer layer 226 is deposited conformally over the workpiece 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

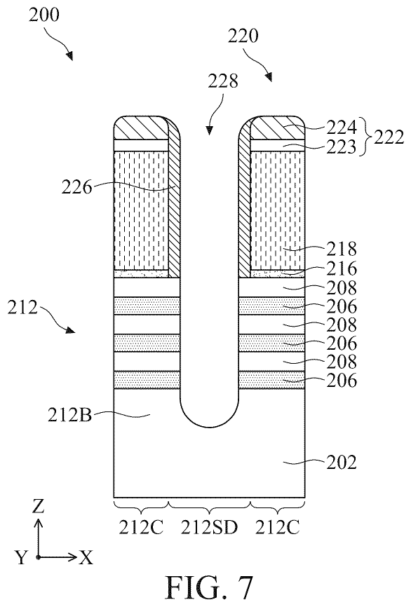

Referring to FIGS. 1 and 7, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

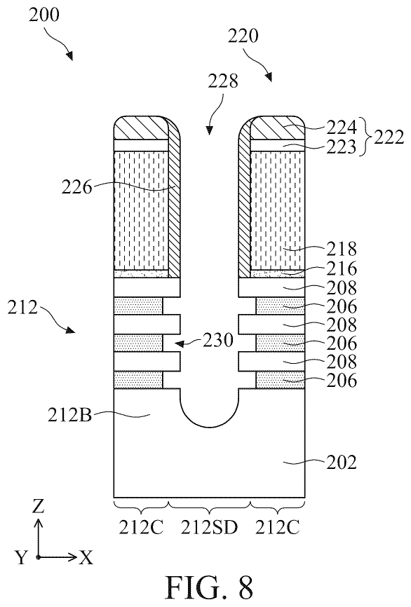

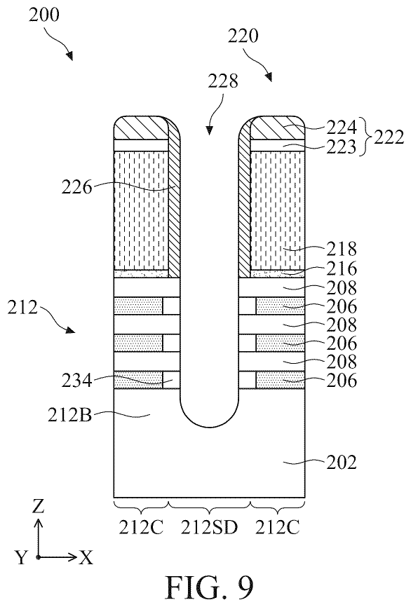

Referring to FIGS. 1, 8 and 9, method 100 includes a block 112 where inner spacer features 234 are formed. While not shown explicitly, operation at block 112 may include selective and partial removal of the sacrificial layers 206 to form inner spacer recesses 230 (shown in FIG. 8), deposition of inner spacer material over the workpiece 200, and etch back the inner spacer material to form inner spacer features 234 in the inner spacer recesses 230 (shown in FIG. 9). Referring to FIG. 8, the sacrificial layers 206 exposed in the source/drain trenches 228 are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses 230 are formed, an inner spacer material is deposited over the workpiece 200, including over the inner spacer recesses 230. The inner spacer material may include metal oxides, silicon oxide, silicon oxycarbonitride, silicon nitride, silicon oxynitride, carbon-rich silicon carbonitride, or other dielectric materials. The metal oxides may include aluminum oxide, zirconium oxide, tantalum oxide, yttrium oxide, titanium oxide, lanthanum oxide, hafnium oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 234 in the inner spacer recesses 230. At block 112, the inner spacer material may also be removed from the top surfaces and/or sidewalls of the gate-top hard mask layer 222 and the gate spacer layer 226. As shown in FIG. 9, each of the inner spacer features 234 is in direct contact with the recessed sacrificial layers 206 and is disposed vertically (along the Z direction) between two neighboring channel layers 208.

While not explicitly shown, before any of the epitaxial layers are formed, method 100 may include a cleaning process to clean surfaces of the workpiece 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

Referring to FIGS. 1 and 10-13B, method 100 includes a block 114 where a source/drain feature 240 is formed over the source/drain region 212SD.

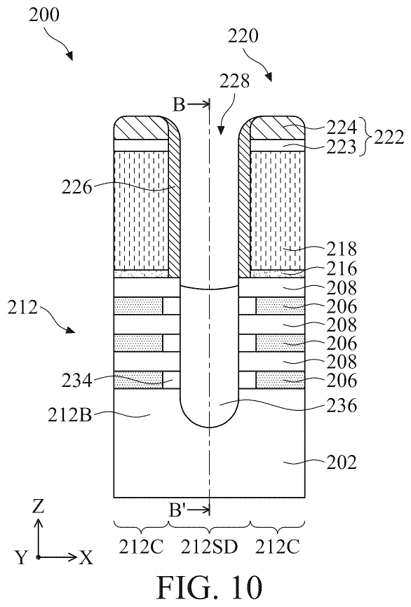

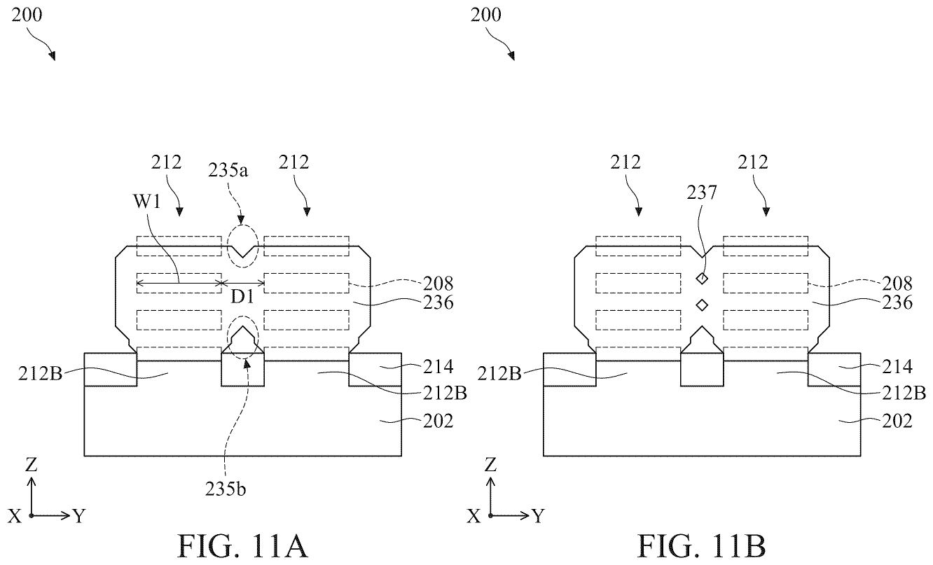

Referring to FIGS. 10-11B, operations at block 114 include forming a first epitaxial layer 236 over the source/drain region 212SD. In some implementations, the first epitaxial layer 236 may be epitaxially and selectively formed from the exposed sidewalls of the channel layers 208 and exposed surfaces of the base fin structures 212B. Suitable epitaxial processes for block 114 include vapor-phase epitaxy (VPE), ultra-high vacuum CVD (UHV-CVD), molecular beam epitaxy (MBE), and/or other suitable processes. The epitaxial growth process at block 114 may use gaseous precursors, which interact with the composition of the channel layers 208 and the base fin structures 212B. The first epitaxial layer 236 is allowed to overgrow and merge over the inner spacer features 234 and substantially fill the source/drain trenches 228. In some implementations, the first epitaxial layer 236 is doped during deposition by adding impurities to a source material of the epitaxy process. In some implementations, the first epitaxial layer 236 is doped by an ion implantation process subsequent to a deposition process.

In some embodiments, when a p-type device (e.g., transistor) is desired, the first epitaxial layer 236 includes silicon germanium (SiGe) and is doped with a p-type dopant, such as boron (B). In some embodiments, the first epitaxial layer 236 includes a germanium (Ge) content between about 10% and 30%. This Ge content range is not trivial. When the germanium content is greater than about 30%, the lattice mismatch between silicon and germanium may cause too much defect at the interface between the first epitaxial layer 236 and the channel layers 208, which may lead to increased resistance or device failure. When the germanium content is smaller than about 10%, the channel layers 208 may not be sufficiently strained for improved hole mobility. A concentration of the p-type dopant in the first epitaxial layer 236 may be between about 2×10²¹ atoms/cm³ and about 1×10²¹ atoms/cm³.

In some embodiments, when an n-type device (e.g., transistor) is desired, the first epitaxial layer 236 includes silicon that is in-situ doped with an n-type dopant, such as arsenic (As), phosphorus (P), antimony (Sb), or a combination thereof. In some embodiments, the first epitaxial layer 236 is doped with P. In some embodiments, the first epitaxial layer 236 includes Si, GaAs, GaAsP, SiP, or other suitable material. A concentration of the n-type dopant in the first epitaxial layer 236 may be between about 1×10²¹ atoms/cm³ and about 5×10²¹ atoms/cm³.

The dopant type and dopant quantity affect the conductivity of the region, the lattice mismatch (e.g., stress) between the first epitaxial layer 236 and the channel layers 208 and the base fin structure 212B, and the epitaxial growth rate and facet formation. Too low of a dopant concentration provides insufficient carriers to form the semiconductor device 200; too high of dopant concentration increases the lattice mismatch with the underlying layers among other possible concerns.

FIG. 11A illustrates a fragmentary cross-sectional view of the workpiece 200 taken along line B-B′ as in FIG. 10. In some embodiments, the two fin-shaped structures 212 are disposed adjacent to each other, their respective first epitaxial layers 236 on the base fin structures 212B merge into each other during the epitaxial growth process. In the depicted embodiment, a top surface of the first epitaxial layer 236 is below a top surface of a topmost channel layer 208. The merged first epitaxial layer 236 may have top surfaces having a curved or a non-linear profile 235a and bottom surfaces having a curved or a non-linear profile 235b. In some embodiments, the profile 235a is a concaved profile. In some embodiments, the profile 235b is a concaved profile. Although not depicted, it is understood that the first epitaxial layers 236 of more than two (e.g., three, four) fin shaped structures 212 adjacent to each other may merge into each other.

The channel layers may have a width W1 of about 5 nm to about 50 nm along the Y-direction as depicted. A distance D1 between two channel layers 208 in the neighboring fin-shaped structures 212 along the Y-direction may be about 5 nm to about 20 nm. A ratio of W1 to D1 may be in a range of equal to and greater than about 1 to equal to and less than about 10. If W1/D1 is too large (e.g., greater than 10), W1 may be too large, the benefits of short channel effect and drain-induced barrier lowering (DIBL) reduction of the semiconductor device 200 may be less or insignificant. If W1/D1 is too small (e.g., less than 1), W1 may be too small, and the drive current in the channel layers 208 may be too small.

FIG. 11B illustrates an alternative fragmentary cross-sectional view of the workpiece 200 taken along line B-B′ as in FIG. 10. In such embodiments, a difference from the embodiments illustrated in FIG. 11A includes that, the merging of the two first epitaxial layers 236 may leave voids 237 therebetween. This may be because the first epitaxial layers 236 are epitaxially and selectively formed from the respective exposed sidewalls of the channel layers 208 and exposed surface of the base fin structure 212B. In some embodiments, the void 237 has one or two opening(s) to the environment along the X-direction. In some other embodiments, the void 237 does not have opening(s) to the environment and is enclosed by the first epitaxial layers 236.

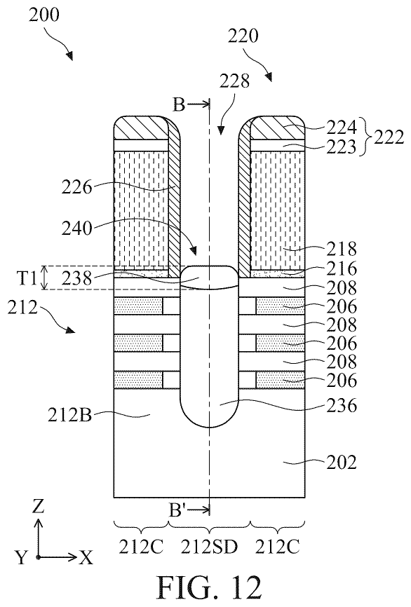

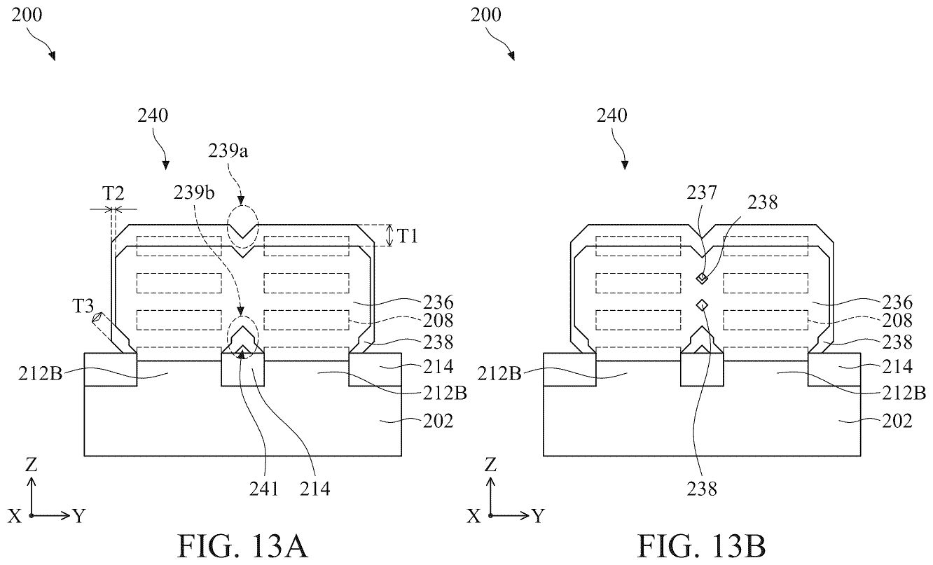

Referring to FIGS. 12-13B, operations at block 114 includes forming a second epitaxial layer 238 over the first epitaxial layer 236. In some embodiments, the second epitaxial layer 238 may be epitaxially and selectively formed from the first epitaxial layer 236. Suitable epitaxial processes include vapor-phase epitaxy (VPE), ultra-high vacuum CVD (UHV-CVD), molecular beam epitaxy (MBE), and/or other suitable processes. The epitaxial growth process may use gaseous precursors, which interact with the composition of the first epitaxial layer 236. In some embodiments, the second epitaxial layer 238 is grown from a seed that includes the surface of the first epitaxial layer 236. In some implementations, the second epitaxial layer 238 is doped during deposition by adding impurities to a source material of the epitaxy process. In some implementations, the second epitaxial layer 238 is doped by an ion implantation process subsequent to a deposition process. According to the present disclosure, a volume of the second epitaxial layer 238 is less than a volume of the first epitaxial layer 236.

In some embodiments, when a p-type device (e.g., transistor) is desired, the second epitaxial layer 238 includes SiGe and is doped with a p-type dopant, such as B. In some embodiments, the second epitaxial layer 238 includes a Ge content greater than the Ge content of the first epitaxial layer 236. In some embodiments, the second epitaxial layer 238 includes a Ge content between about 25% and 65%. A concentration of the p-type dopant in the second epitaxial layer 238 may be between about 5×10²⁰ atoms/cm³ and about 2×10²¹ atoms/cm³.

In some embodiments, when an n-type device (e.g., transistor) is desired, the second epitaxial layer 238 includes silicon that is in-situ doped with an n-type dopant, such as As, P, Sb, or a combination thereof. In some embodiments, the second epitaxial layer 238 is doped with P. In some embodiments, the second epitaxial layer 238 includes Si, GaAs, GaAsP, SiP, or other suitable material. A concentration of the n-type dopant in the second epitaxial layer 238 may be between about 2×10²¹ atoms/cm³ and about 1×10²² atoms/cm³.

The dopant type and dopant quantity affect the conductivity of the region, the lattice mismatch (e.g., stress) between the first epitaxial layer 236 and the second epitaxial layer 238, and the epitaxial growth rate and facet formation. Too low of a dopant concentration provides insufficient carriers to form the semiconductor device 200; too high of dopant concentration increases the lattice mismatch with the underlying layers among other possible concerns. The concentration of the dopant in the second epitaxial layer 238 may be greater than the concentration of the dopant in the first epitaxial layer 236. The increasing dopant concentration may serve to provide the appropriate functionality to the semiconductor device 200 while also reducing the resistance of the source/drain feature 240.

FIG. 13A illustrates a fragmentary cross-sectional view of the workpiece 200 taken along line B-B′ as in FIG. 12. The second epitaxial layer 238 may be grown from all exposed surfaces of the first epitaxial layer 236, thus the second epitaxial layer 238 follows the outline of the first epitaxial layer 236. In some embodiments, the second epitaxial layer 238 has top surfaces having a curved or a non-linear profile 239a and bottom surfaces having a curved or a non-linear profile 239b. In some embodiments, the profile 239a is a concaved profile. In some embodiments, the profile 239b is a concaved profile. The workpiece 200 may include a void 241 between the bottom surfaces of the second epitaxial layer 238 and the isolation feature 214 therebelow. In some embodiments, the second epitaxial layer 238 includes a first portion disposed over top surfaces of the first epitaxial layer 236 and a second portion disposed along sidewalls of the first epitaxial layer 236. The first portion may provide landing place for a source/drain contact and/or for a silicide layer to be formed later. A bottom surface of the first portion is below a top surface of the topmost channel layer 208. The first portion may have a thickness T1 along a vertical direction and the second portion may have a thickness T2 along a horizontal direction. T1 may be about 5 nm to about 20 nm. T2 may be controlled to be equal to or less than about 5 nm to prevent the source/drain feature 240 from merging with epitaxial layers of a neighboring semiconductor device (e.g., as in region 325 in FIG. 19, to be described below). In some examples, T2 is about 1 nm to about 5 nm. In some embodiments, a ratio of T1 to T2 is equal to or greater than about 2. If the ratio is too small, the second epitaxial layer 238 may be too thin to provide a landing place for a source/drain contact and/or for a silicide layer to be formed later. In the depicted embodiment, the second epitaxial layer 238 further includes a third portion disposed below the first epitaxial layer 236 and having a thickness T3 of a range between T1 and T2. The different thicknesses may result from controlled growth of the second epitaxial layer 238 in different directions. For example, selective growth, radical growth, deposition and etching may be used in the forming of the second epitaxial layer 238.

FIG. 13B illustrates an alternative fragmentary cross-sectional view of the workpiece 200 taken along line B-B′ as in FIG. 12. In such embodiments, a difference from the embodiments illustrated in FIG. 13A includes that, the merging of the two first epitaxial layers 236 may leave voids 237 therebetween as in FIG. 11B. The second epitaxial layer 238 is formed to partially (as the top void 237 in FIG. 13B) or completely (as the bottom void 237 in FIG. 13B) fill the void 237.

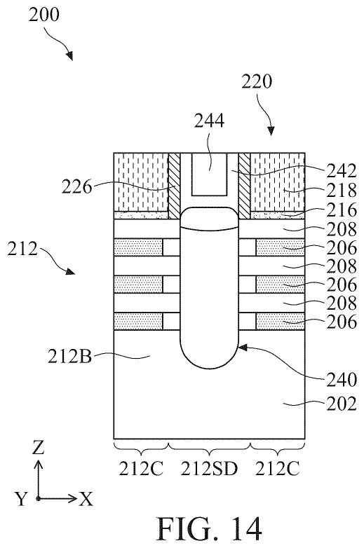

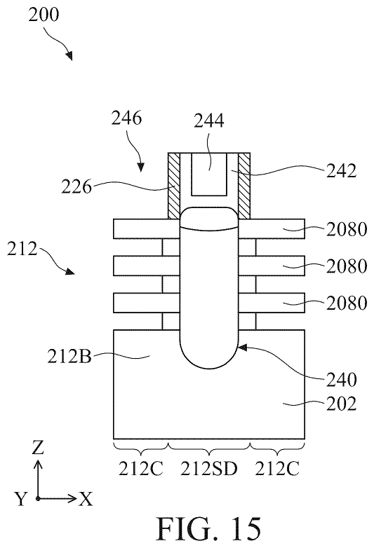

Referring to FIGS. 1 and 14-15, method 100 includes a block 116 where the dummy gate stack 220 is removed. Block 116 may include depositing a contact etch stop layer (CESL) 242 and an interlayer dielectric (ILD) layer 244 over the source/drain feature 240, and removing the dummy gate stack 220. Referring to FIG. 14, the CESL 242 is deposited over the workpiece 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220. Referring to FIG. 15, the dummy gate stack 220 is removed. The removal of the dummy gate stack 220 may include one or more etching processes that are selective to the material of the dummy gate stack 220. For example, the removal of the dummy gate stack 220 may be performed using a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed.

Still referring to FIGS. 1 and 15, method 100 includes a block 118 where the plurality of channel layers 208 are released as channel members 2080. After the removal of the dummy gate stack 220, the sacrificial layers 206 between the channel layers 208 in the channel region 212C are selectively removed. The selective removal of the sacrificial layers 206 releases the channel layers 208 (shown in FIG. 14) to form channel members 2080 shown in FIG. 15. The selective removal of the sacrificial layers 206 forms a gate trench 246 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

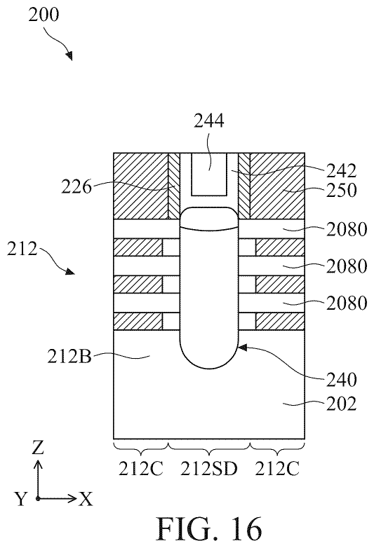

Referring to FIGS. 1 and 16, method 100 includes a block 120 where a gate structure 250 is formed to wrap around each of released as channel members 2080. After the release of the channel members 2080, the gate structure 250 is formed to wrap around each of the channel members 2080. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C.

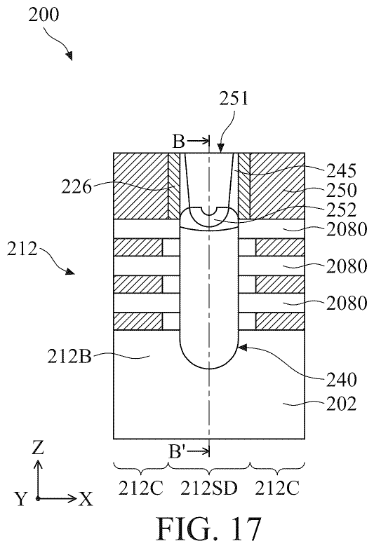

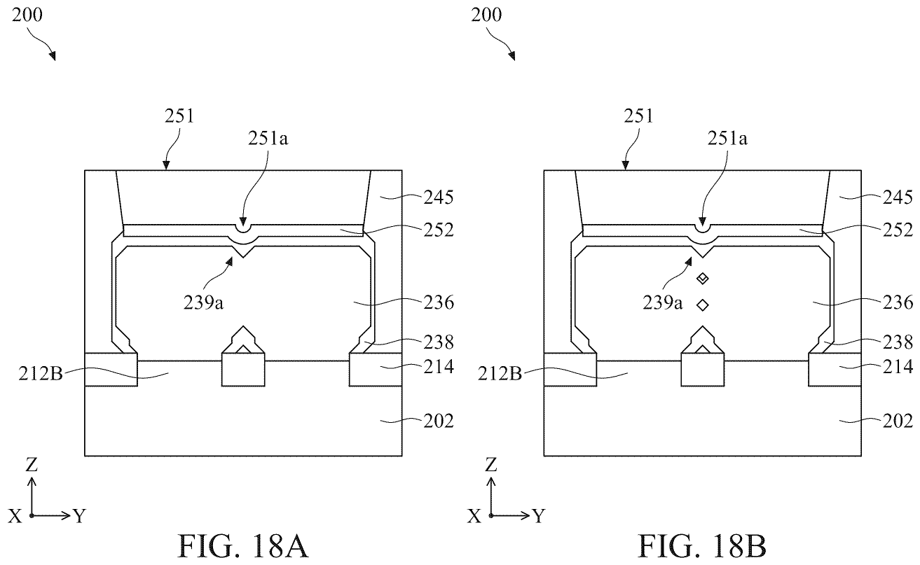

Referring to FIGS. 1 and 17-18B, method 100 includes a block 122 where a source/drain contact 251 is formed over the source/drain feature 240. For the purpose of simplicity, in FIGS. 17-18B, the CESL 242 and the ILD layer 244 are depicted as a combined dielectric layer 245. In some embodiments, an opening is formed in the dielectric layer 245 over the source/drain feature 240. The opening may be performed by patterning a hard mask or photoresist masking element to define the opening and etching the dielectric layer 245 through the opening. Patterning may also be implemented or replaced by other proper methods, such as maskless photolithography, electron-beam writing, ion-beam writing, and molecular imprint. The removing process to form the opening may include a plasma etch, a reaction ion etch (RIE), a dry etch, a wet etch, another proper removing process, or combinations thereof.

A contact fill metal or metals (e.g., copper, tungsten) are then formed in the opening and interfacing the source/drain feature 240. Various deposition process may be applied to deposit material forming the source/drain contact 251. For example, the deposition of copper may include PVD to form a seed layer and plating to form bulk copper on the copper seed layer. In some embodiments, prior to filling conductive material in contact openings, a silicide layer 252 may be formed on the source/drain feature 240 (e.g., on the second epitaxial layer 238) to further reduce the contact resistance. The silicide layer 252 may be above the first epitaxial layer 236 and may be separated from the first epitaxial layer 236 by the second epitaxial layer 238. In some embodiments, the process may convert a portion of the second epitaxial layer 238 to the silicide layer 252. The silicide layer 252 includes silicon and metal, such as titanium silicide, tantalum silicide, nickel silicide or cobalt silicide. The silicide layer 252 may be formed by a process referred to as self-aligned silicide (or salicide). The process includes metal deposition, annealing to react the metal with silicon, and etching to remove unreacted metal. Filling the contact openings form the source/drain contact 251 as illustrated in FIGS. 17-18B.

As depicted in FIGS. 17-18B, the source/drain contact 251 lands on a top surface of the source/drain feature 240 that is disposed over two or more base fin structures 212B. This allows for proper landing of the source/drain contact 251 onto the source/drain feature 240 and suitable interface between the features reducing contact resistance. A bottom surface of the source/drain contact 251 may have a convex profile 251a over the concaved profile 239a of the source/drain feature 240.

The semiconductor device 200 may undergo further processing to form various features and regions known in the art. For example, subsequent processing may form additional interlayer dielectric (ILD) layer(s), additional contacts/vias/lines and multilayers interconnect features (e.g., metal layers and interlayer dielectrics) on the substrate 202, configured to connect the various features to form a functional circuit that may include one or more devices including semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

FIG. 19 illustrates a fragmentary top view of an exemplary semiconductor structure 300, according to one or more aspects of the present disclosure. In some embodiments, the semiconductor structure 300 includes a first region 305, a second region 315, and a third region 325. The third region 325 may include the semiconductor device 200 described above. The first region 305 and the second region 315 may include GAA devices as shown in FIGS. 20A and 20B, which illustrate fragmentary cross-sectional views taken along line C-C′ and D-D′ as in FIG. 19, respectively.

The first region 305, the second region 315, and the third region 325 may each include one or more n-type active regions 212a forming n-type transistors and one or more p-type active regions 212b forming p-type transistors. The n-type active regions 212a and the p-type active regions 212b may be individually or collectively referred to as active regions 212 or fin-shaped structures 212 as the context requires. In each of the regions 305, 315, and 325, a gate structure 250 is disposed over the active regions and gate spacer layers 226 are disposed along sidewalls of the gate structure 250. In the regions 305 and 315, each of the active regions 212 and the corresponding gate structure 250 disposed thereover form a transistor (e.g., a GAA device). As compared to the workpiece 200, a difference of the GAA devices in the first region 305 and the second region 315 include that, each source/drain feature 340 is disposed on a single fin base structure 212B, and the dimension difference are to be described below.

In the first region 305, the active regions 212 may each have a width W2 of about 5 nm to about 50 nm, a distance D2 between two neighboring active regions 212 may be about 25 nm to about 100 nm, alternatively may be about 25 nm to about 50 nm. In some embodiments, W2 is about the same as W1. In the second region 315, the active regions 212 may each have a width W3 of about 20 nm to about 200 nm, a distance D3 between two neighboring active regions 212 may be about 25 nm to about 50 nm. In some embodiments, W3 is greater than W2 and is greater than W1. In the third region 325, the active regions 212 may each have the width W1 as described above, a distance between two neighboring active regions 212 is D1 as described above. D1 is smaller than D2 and D3, so that the source/drain features 240 are merged source/drain features as described above. The merged source/drain features 240 may have a width W4. In some embodiments, a total width W5 of the active regions 212a (or 212b) and space therebetween as depicted may be about the same as W3. W5 may be equal to or smaller than W4. A ratio of W1 to D1, a ratio of W2 to D2, and a ratio of W3 to D3 may be different. In some embodiments, the ratio of W1/D1 is greater than the ratio of W2/D2. In some embodiments, the ratio of W3/D3 is greater than the ratio of W1/D1 and greater than the ratio of W2/D2. The dimensions W1, W2, W3, W4, W5, D1, D2, and D3 are all along the Y-direction. The neighboring active regions 212a (or 212b) and space therebetween may collectively form a combined active region 254n (or 254p) as illustrated by the dashed rectangle. In some embodiments, the combined active region 254n (or 254p) may include two or more (e.g., three, four) active regions 212a (or 212b), which include source/drain features 240 merged into each other. The combined active region 254n (or 254p) and the corresponding gate structure 250 in the third region 325 may form a transistor. A distance between the neighboring combined active regions may be D3 as described above.

While having merged source/drain features 240, the combined active region 254n (or 254p) has a total channel width Wt (e.g., Wt=2×W1 for the combined active region 254n in FIG. 19) greater than the channel width W1 of each active region 212 in the region 325, and greater than the channel width W2 of each active region 212 in the region 305. In addition, the gate structure 250 is disposed between adjacent active regions 212 in the combined active region 254n (or 254p) and wraps around each channel layers thereof, thus the control by the gate structure to the channel layers in the combined active region 254n (or 254p) may be increased, and process window of metal gate replacement processes in blocks 116-120, such as metal gate patterning processes, may also be increased. In some embodiments, during operation, the devices in the first region 305 have relatively small current, and the devices in the regions 315 and 325 have relatively large current, which may result from channel width differences (e.g., W3>W2 and Wt>W2). In some embodiments, short channel effect and drain-induced barrier lowering (DIBL) of the devices in the regions 305 and 325 are less compared to the devices in the second region 315, which may result from channel width differences (e.g., W2<W3 and W1<W3). The regions 305, 315, and 325 may be designed for different device purposes.

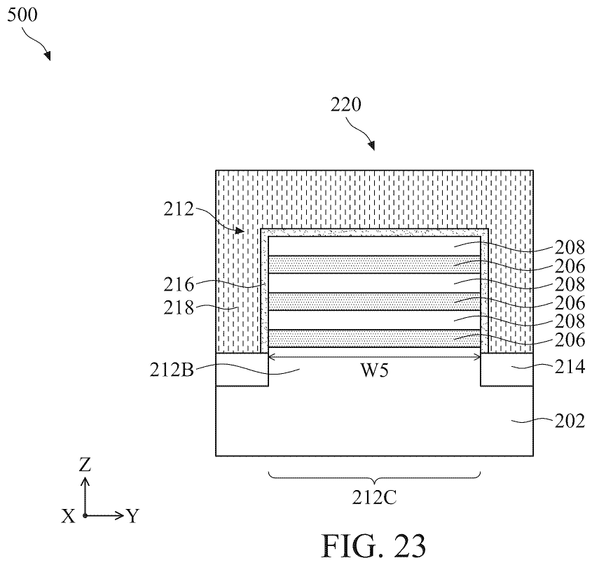

Method 400 in FIG. 21 is an example method for forming an alternative semiconductor structure 500. Method 400 continues from block 112 of method 100 in FIG. 1. Referring to FIGS. 21-25, method 400 includes a block 402 where a source/drain feature 540 is formed in the source/drain recess of the workpiece 500. FIG. 22 illustrates a fragmentary top view of the workpiece 500 at block 402. FIGS. 23-25 illustrate fragmentary cross-sectional views of the workpiece 500 taken along line D-D′, E-E′, and C-C′ as in FIG. 22, respectively. The operations in block 402 are similar to those described in block 114 of method 100. The source/drain feature 540 includes the first epitaxial layer 236 and the second epitaxial layer 238 similar as described above. As compared to the workpiece 200 illustrated in FIGS. 12-13B, differences of the workpiece 500 may include the following. Each source/drain feature 540 of the workpiece 500 may be disposed on a single fin base structure 212B. The source/drain feature 540 may include a relatively flat top surface (e.g., without a concaved profile formed by merged source/drain features). The channel regions 208 may have the width W5 and the source/drain feature 540 may have the width W4 as described above.

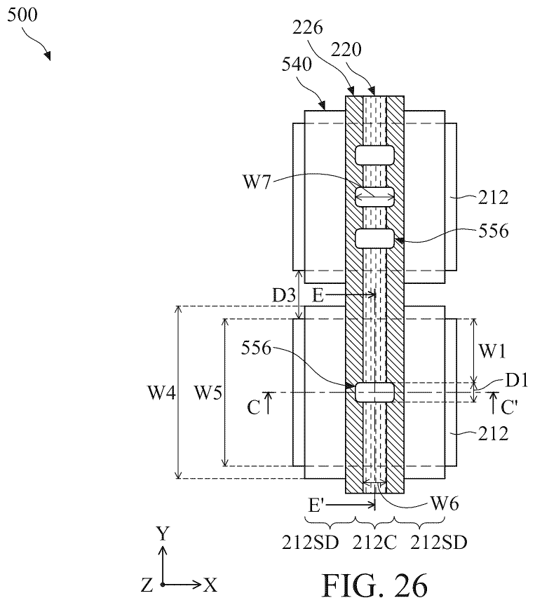

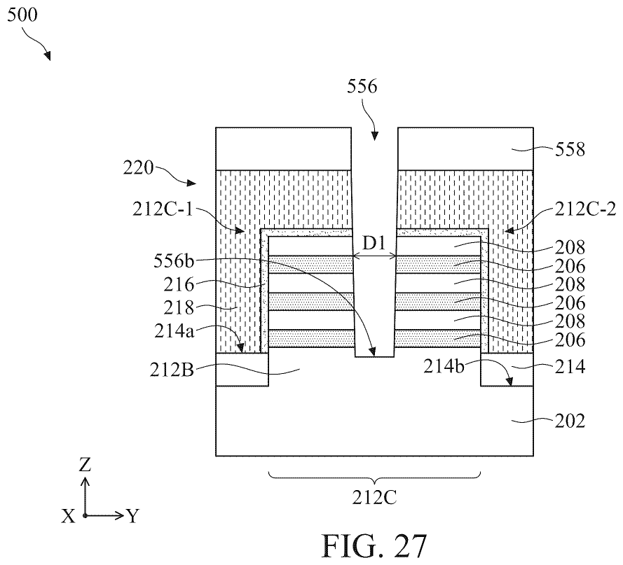

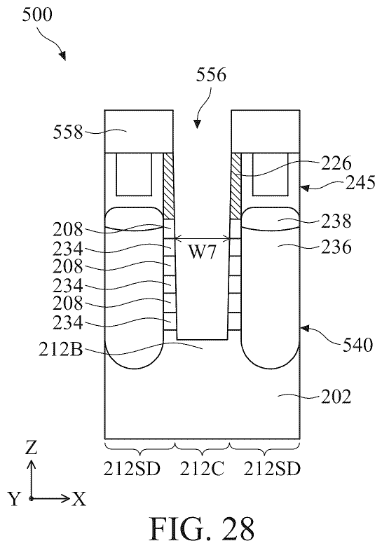

Referring to FIGS. 21 and 26-28, method 400 includes a block 404 where a trench 556 is formed in the dummy gate stack 220 and the fin-shaped structure 212. The channel region 212C (as in FIG. 23) may be cut to form sub-regions (e.g., 212C-1 and 212C-2) by the trench 556. FIG. 26 illustrates a fragmentary top view of the workpiece 500 at block 404 and FIGS. 27-28 illustrate fragmentary cross-sectional views taken along line E-E′ and C-C′ as in FIG. 26, respectively. Forming the trench 556 may include forming a hard mask layer 558 over the workpiece 500, patterning the hard mask layer 558 to form an opening, and etching the dummy gate stack 220 and the fin-shaped structure 212 using the patterned hard mask layer 558 as an etch mask. The hard mask layer 558 may be removed after forming the trench 556.

In an embodiment, photolithography process(es) and etching process(es) are performed to the workpiece 200 to form the trench 556. Portions of the dummy gate stack 220 and the fin-shaped structure 212 are removed to form the trench 556. The etching process(es) may include wet etch, dry etch, or a combination thereof. The etching process(es) may use one or more etchant. In an example process, the hard mask layer 558 and a photoresist (not depicted) are deposited over the workpiece 500. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer 558 to form a patterned hard mask layer 558 as depicted in FIGS. 27-28. The patterned hard mask layer 558 is then applied as an etch mask to etch the dummy gate stack 220 and the fin-shaped structure 212. The etch process may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, oxygen, hydrogen, other suitable gases, or combinations thereof.

In some implementations, the trench 556 has tapered sidewalls. For example, a width of a bottom of the trench 556 may be smaller than a width of a top of the trench 556 along the Y-direction and/or along the X-direction. Thus, widths along the Y-direction of the channel layers 208 of each sub-regions (e.g., 212C-1 and 212C-2) may gradually increase from top to bottom. In the present embodiments, the trench 556 extends through the dummy electrode layer 218, the dummy dielectric layer 216, and extends downward into the fin-shaped structure 212 as shown in FIGS. 27-28. The trench 556 may extend through at least one channel layer 208 and at least one sacrificial layer 206. In some embodiments, the trench 556 extends through the channel layers 208 and the sacrificial layers 206. In the depicted embodiment, the trench 556 further extends into the fin base structure 212B. In some embodiments, a bottom surface 556b of the trench 556 is lower than a bottom surface of the topmost sacrificial layer 206. In some embodiments, the bottom surface 556b is lower than a bottom surface of the bottommost sacrificial layer 206. In some embodiments, the bottom surface 556b is lower than a top surface 214a of the isolation feature 214 and higher than a bottom surface 214b of the isolation feature 214.

In the depicted embodiment, the dummy gate stack 220 has a width W6 of about 5 nm to about 20 nm along the X-direction. The trench 556 has a width W7 of about 15 nm to about 30 nm along the X-direction. As depicted in FIG. 26, W7 is greater than W6. In such embodiments, portions of the gate spacer layers 226 and/or the inner spacer features 234 are removed to form the trench 556. The trench 556 does not extend through the gate spacer layers 226 or the inner spacer features 234 along the X-direction. In other words, portions of the gate spacer layers 226 inner spacer features 234 remain between the trench 556 and the adjacent source/drain feature 540, as depicted in FIG. 28. In some other embodiments not depicted, W7 is about the same as W6. In such embodiments, the gate spacer layers 226 and/or the inner spacer features 234 are not removed when forming the trench 556.

In some embodiments as the active region 212 at the bottom of FIG. 26 and in FIG. 27, one trench 556 is formed in the active region 212, and a top portion of the channel region 212C of the active region 212 is cut into two sub-regions 212-1 and 212-2 (also referred to as sub fin-shaped structures 212-1 and 212-2). The sub-regions include stacks of semiconductor layers disposed over a same base fin structure 212B. In some other embodiments, more than one (e.g., two, three) trenches 556 are formed in the channel region 212C. For example, in the active region 212 at the top of FIG. 26, three trenches 556 are formed, thus a top portion of the channel region 212C of the active region 212 is cut into four sub-regions. The numbers of the sub-regions in the active regions 212 are for illustration purpose only and should not be construed as limiting the scope of the present disclosure. A sub-region may have the width W1 as described above and the trench 556 may have the width D1 as described above. A distance between the active regions 212 may be D3 as described above.

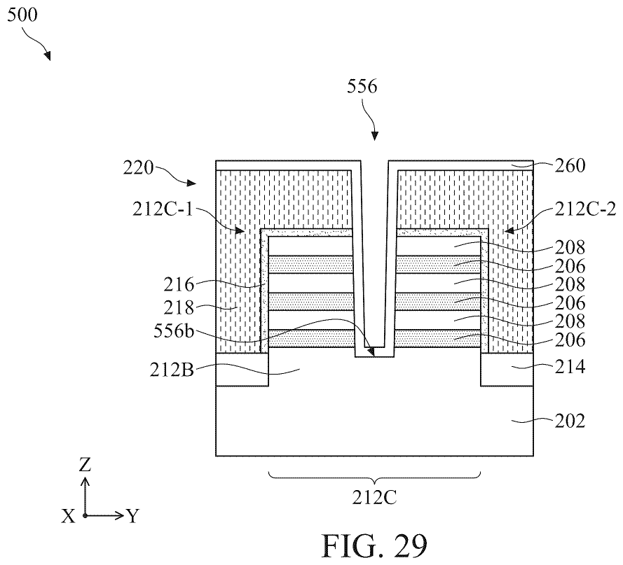

Referring to FIGS. 21 and 29, method 400 includes a block 406 where a dielectric layer 260 is deposited over the workpiece 500 using a suitable deposition technique, such as an ALD process, a PVD process or a CVD process. FIG. 29 illustrates a fragmentary cross-sectional view of the workpiece 500 at block 406. The dielectric layer 260 may be deposited over the bottom surface 556b and sidewalls of the trenches 256 and on top surfaces of the dummy gate stack 220. The deposition may be conformal. The dielectric layer 260 may have a thickness of about 0.5 nm to about 2 nm. In some embodiments, the dielectric layer 260 includes an oxide layer, such as a silicon oxide layer (SiO₂). The dielectric layer 260 may be for control of a following CMP process to be described below.

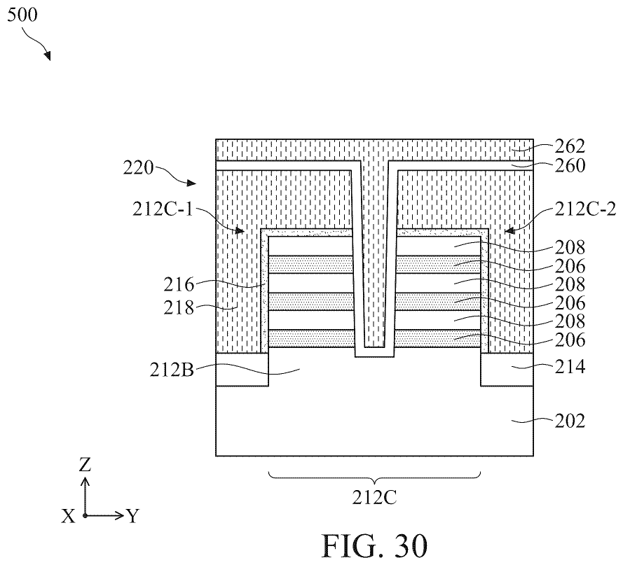

Referring to FIGS. 21 and 30, method 400 includes a block 408 where a polycrystalline semiconductor material 262 is deposited over the workpiece 500 using a suitable deposition technique, such as an ALD process, a PVD process or a CVD process. FIG. 30 illustrates a fragmentary cross-sectional view of the workpiece 500 at block 408. The polycrystalline semiconductor material 262 may be deposited to fill the trenches 256, over the dielectric layer 260, and over the dummy gate stack 220. In some embodiments, the polycrystalline semiconductor material 262 includes polysilicon.

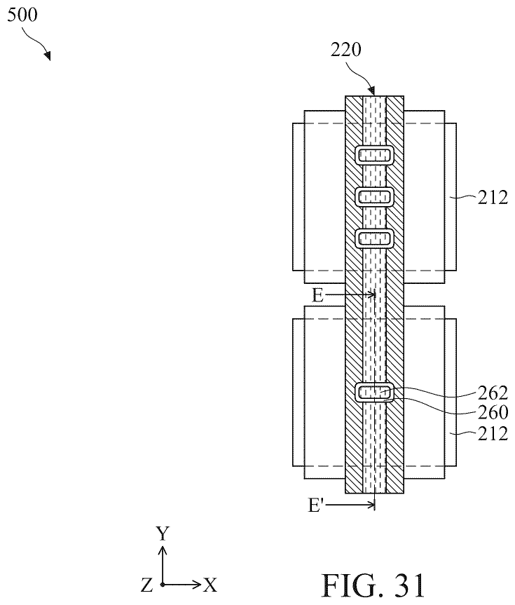

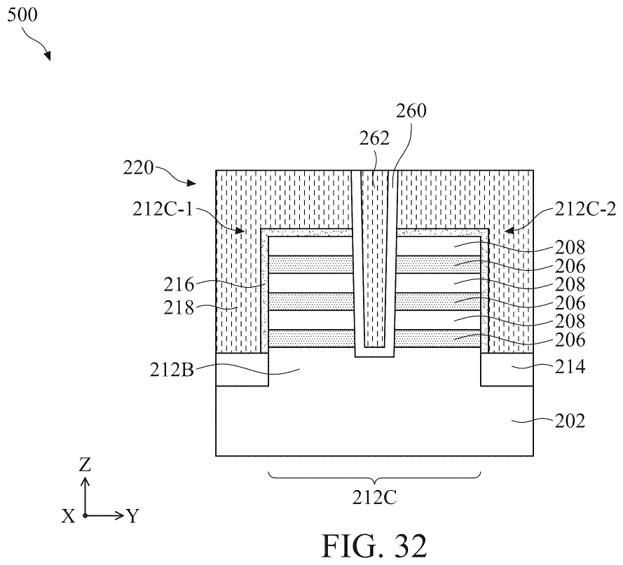

Referring to FIGS. 21 and 31-32, method 400 includes a block 410 where a CMP process is performed to remove portions of the polycrystalline semiconductor material 262 and the dielectric layer 260 and to expose top surfaces of the dummy gate stack 220. FIG. 31 illustrates a fragmentary top view of the workpiece 500 at block 410 and FIG. 32 illustrates a fragmentary cross-sectional view taken along line E-E′ as in FIG. 31. The CMP process removes the polycrystalline semiconductor material 262 and the dielectric layer 260 over the top surfaces of the dummy gate stack 220. A top portion of the dummy electrode layer 218 may also be removed in the CMP process.

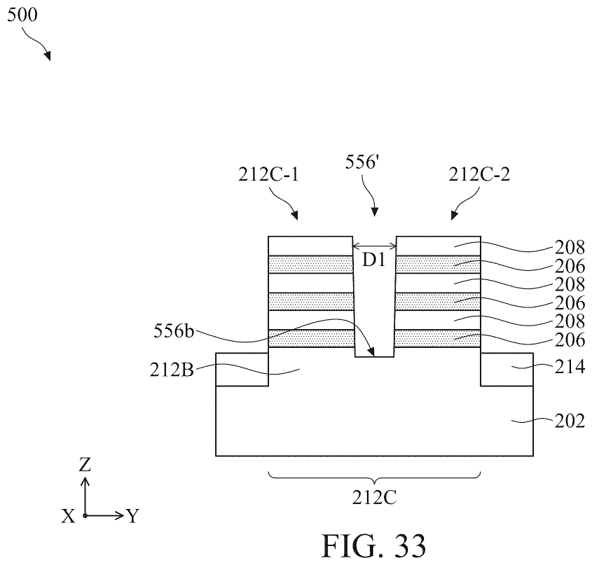

Referring to FIGS. 21 and 33, method 400 includes a block 412 where the polycrystalline semiconductor material 262, the dielectric layer 260, and the dummy gate stack 220 are removed. FIG. 33 illustrates a fragmentary cross-sectional view of the workpiece 500 at block 412. Operations of block 412 may be similar to those of block 116 of method 100 as described above. Differences include that, the polycrystalline semiconductor material 262 and the dielectric layer 260 are also removed in block 412. The removal of the polycrystalline semiconductor material 262 and the dielectric layer 260 may include one or more etching processes that are selective to the materials of the polycrystalline semiconductor material 262 and/or the dielectric layer 260. For example, the removal may be performed using a selective wet etch, a selective dry etch, or a combination thereof that is selective to the polycrystalline semiconductor material 262 and/or the dielectric layer 260. After the removal of the polycrystalline semiconductor material 262, the dielectric layer 260, and the dummy gate stack 220, sidewalls of the channel layers 208 and the sacrificial layers 206 in the sub-regions (e.g., 212C-1 and 212C-2) are exposed. A trench 556′ having similar width along the Y-direction as the trench 556 is formed between the adjacent sub-regions (e.g., 212C-1 and 212C-2). The trench 556′ includes a bottom portion of the trench 556. The bottom surface 556b of the trench 556′ is exposed.

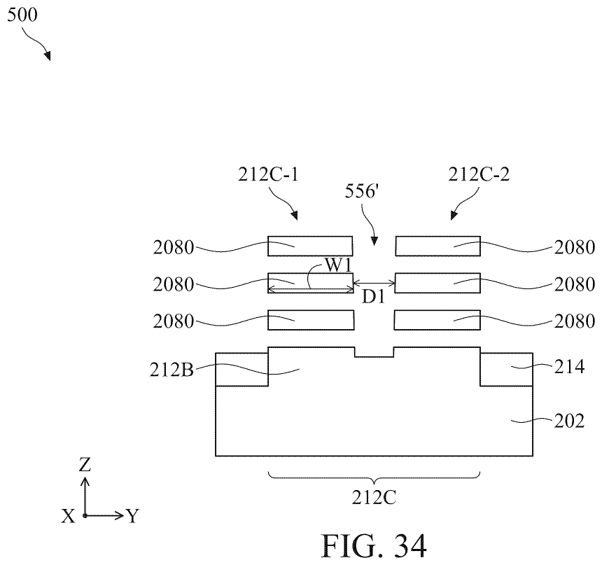

Referring to FIGS. 21 and 34, method 400 includes a block 414 where the plurality of channel layers 208 are released as channel members 2080. FIG. 34 illustrates a fragmentary cross-sectional view of the workpiece 500 at block 414. Operations of block 414 are similar to those of block 118 of method 100 as described above. Differences include that, a stack of channel members 2080 is formed in each of the sub-regions (e.g., 212C-1 and 212C-2). The channel members 2080 have the width W1 as described above along the Y-direction, the neighboring stacks are spaced apart from each other by the distance D1 as described above, and W1/D1 may be as described above.

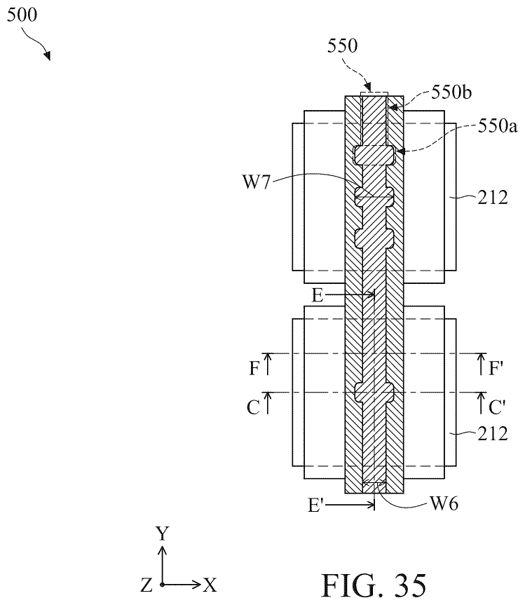

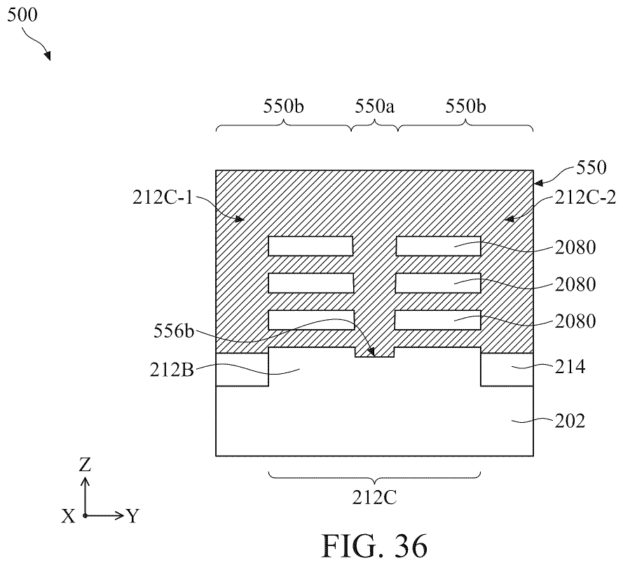

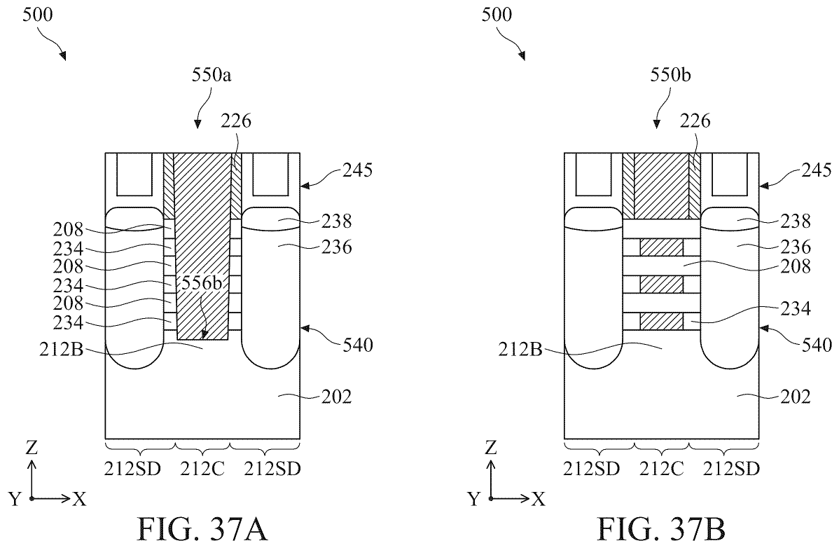

Referring to FIGS. 21 and 35-37B, method 400 includes a block 416 where a gate structure 550 is formed to wrap around each of the channel members 2080. FIG. 35 illustrates a fragmentary cross-sectional view of the workpiece 500 at block 416 and FIGS. 36-37B illustrate fragmentary cross-sectional views taken along line E-E′, C-C′, and F-F′ as in FIG. 35, respectively. Operations of block 416 may be similar to those of block 120 of method 100 as described above and the gate structure 550 is similar to the gate structure 250. Differences include that, the gate structure 550 is further formed in the trench 556′ between the adjacent sub-regions (e.g., 212C-1 and 212C-2). The gate structure 550 is formed on the bottom surface 556b. From the top view, the gate structure 550 may include joint portions 550a disposed between the neighboring sub-regions of the active region 212 and normal portions 550b elsewhere. The joint portions 550a may have widths similar to the trench 556 or 556′. In the depicted embodiment, the joint portions 550a have the width W7 greater than the width W6 of the normal portions 550b. Referring to FIGS. 37A-37B, thicknesses (along the X-direction) of the gate spacer layers 226 and the inner spacer features 234 disposed along sidewalls of the joint portion 550a are smaller than corresponding thicknesses of the gate spacer layers 226 and the inner spacer features 234 disposed along sidewalls of the normal portion 550b. In some embodiments not depicted, the joint portions 550a and the normal portions 550b have the same width along the X-direction. In such embodiments, the thicknesses of the gate spacer layers 226 and the inner spacer features 234 disposed along sidewalls of the joint portion 550a and the normal portions 550b are the same.

By cutting the top portion of the channel region 212C of the fin-shaped structure 212 into two or more sub-regions, widths of each of the channel members 2080 along the Y-direction may be reduced, thus controls to the channel members 2080 by the gate structure 550 may be improved. The source/drain features 540 are each connected to the channel members 2080 of the two or more sub-regions, and there is no need to form merged source/drain features as in the workpiece 200.

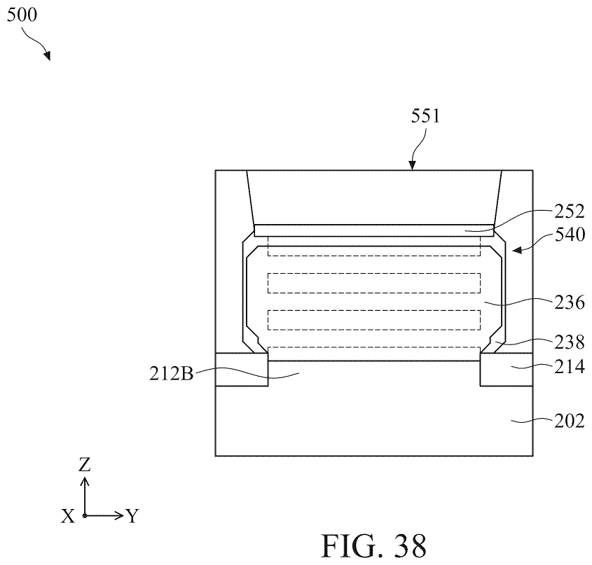

Referring to FIGS. 1 and 38, method 400 includes a block 418 where a source/drain contact 551 is formed to the source/drain feature 540. FIG. 38 illustrates a fragmentary cross-sectional view of the workpiece 500 at block 418. Operations of block 418 may be similar to those of block 122 of method 100 as described above and the source/drain contact 551 may be similar to the source/drain contact 251 described above. Differences include that, the source/drain contact 551 lands over a top surface of the source/drain feature 540 and a bottom surface of the source/drain contact 551 does not have a convex profile.

FIG. 39 illustrates a fragmentary top view of an exemplary semiconductor structure 600, according to one or more aspects of the present disclosure. In some embodiments, the semiconductor structure 600 includes a first region 605, a second region 615, and a third region 625. The first region 605 and the second region 615 are similar to the first region 305 and the second region 315 in FIGS. 19-20B, respectively. The third region 625 may include the semiconductor device 500 described above. In some embodiments, the regions 605, 615, and 625 each include an n-type active region 212a and a p-type active region 212b. Each of the n-type active region 212a and the p-type active regions 212b and the corresponding gate structure 550 disposed thereover form a transistor. The active regions 212 of the third region 625 each include sub-regions (e.g., 212C-1 and 212C-2) in the channel region 212C. The numbers of the sub-regions in the active regions are for illustration purpose only and should not be construed as limiting the scope of the present disclosure.

In the region 625, the active region 212a or 212b has the total channel width Wt (e.g., Wt=2×W1 for the active region 212b in FIG. 39) greater than the channel width W2 of the active region 212a/212b in the region 605. In addition, the gate structure 550 is disposed between adjacent sub-regions (e.g., 212C-1, 212C-2) in the active region 212a/212b and wraps around each channel layers thereof, thus the control by the gate structure 550 to the channel layers in the active region 212a/212b may be increased, and process window of metal gate replacement processes in blocks 412-416, such as metal gate patterning processes, may also be increased. In some embodiments, during operation, the devices in the first region 605 have relatively small current, and the devices in the regions 615 and 625 have relatively large current, which may result from channel width differences (e.g., W3>W2 and Wt>W2). In some embodiments, short channel effect and drain-induced barrier lowering (DIBL) of the devices in the regions 605 and 625 are less compared to the devices in the second region 615, which may result from channel width differences (e.g., W2<W3 and W1<W3). The regions 605, 615, and 625 may be designed for different device purposes.

One of ordinary skill may recognize although FIGS. 2-20B and 22-39 illustrate GAA devices as embodiments, other examples of semiconductor devices may benefit from aspects of the present disclosure, such as FinFET devices.

Although not intended to be limiting, one or more embodiments of the present disclosure provide many benefits to a semiconductor device. For example, the present disclosure reduces short channel effect, sheet-width loading effect, and drain-induced barrier lowering (DIBL) by having two or more channel regions connected to shared source/drain features disclosed herein, which increases control by metal gate structures. Process window of metal gate replacement may also be increased. Thus, the overall performance of the semiconductor device may be improved.

In one exemplary aspect, the present disclosure is directed to a method. The method includes providing a workpiece. The workpiece includes a fin-shaped structure including a fin base and a stack of semiconductor layers over the fin base, a dummy gate structure disposed over the stack of semiconductor layers, and a source/drain feature connected to the channel layers of the stack of semiconductor layers and disposed on a side of the dummy gate structure. The stack of semiconductor layers includes channel layers interleaving with sacrificial layers. The method further includes forming a trench in the dummy gate structure and the fin-shaped structure, depositing a dielectric layer in the trench, depositing a polycrystalline semiconductor material over the dielectric layer, performing a planarization process to the workpiece, and replacing the dielectric layer, the polycrystalline semiconductor material, the dummy gate structure, and the sacrificial layers with a metal gate structure.

In some embodiments, the dummy gate structure extends lengthwise along a direction, the trench cuts a top portion of the fin-shaped structure into two segments, the trench has a first width of about 5 nm to about 20 nm along the direction, and each of the two segments has a second width of about 5 nm to about 50 nm along the direction. In some embodiments, forming the trench includes forming a hard mask over the dummy gate structure, patterning the hard mask to form an opening in the hard mask, and etching the dummy gate structure and the fin-shaped structure using the patterned hard mask as an etch mask to form the trench. In some embodiments, the trench extends through the stack of semiconductor layers and extends into the fin base. In some embodiments, depositing the dielectric layer includes depositing the dielectric layer on a bottom surface and sidewalls of the trench and a top surface of the dummy gate structure. In some embodiments, performing the planarization process includes removing the dielectric layer on the top surface of the dummy gate structure. In some embodiments, the source/drain feature includes a first epitaxial layer disposed over the fin base and a second epitaxial layer disposed over the first epitaxial layer, the second epitaxial layer has a first portion disposed over a top surface of the first epitaxial layer and a second portion disposed along a sidewall of the first epitaxial layer, and the first portion has a first thickness, and the second portion has a second thickness smaller than the first thickness. In some embodiments, the method further includes forming a silicide layer on the second epitaxial layer and forming a source/drain contact over the silicide layer.

In another exemplary aspect, the present disclosure is directed to a method. The method includes providing a workpiece including a substrate and a fin-shaped structure protruding from the substrate. The fin-shaped structure extends lengthwise along a first direction. The method further includes forming a dummy gate structure over the fin-shaped structure and extending lengthwise along a second direction perpendicular to the first direction, forming a gate spacer along a sidewall of the dummy gate structure, forming a source/drain trench in the fin-shaped structure and adjacent to the gate spacer, forming a source/drain feature in the source/drain trench, forming a trench in the dummy gate structure and the fin-shaped structure, filling the trench with a dielectric layer and a polycrystalline semiconductor material, performing a planarization process to the workpiece, and replacing the dielectric layer, the polycrystalline semiconductor material, and the dummy gate structure with a metal gate structure.

In some embodiments, forming the source/drain feature in the source/drain trench includes forming a first epitaxial layer in the source/drain trench, and forming a second epitaxial layer over the first epitaxial layer. The second epitaxial layer has a first portion over a top surface of the first epitaxial layer and a second portion along a sidewall of the first epitaxial layer, and the first portion has a first thickness, and the second portion has a second thickness less than the first thickness. In some embodiments, forming the trench removes a portion of the gate spacer, the dummy gate structure, and the fin-shaped structure. In some embodiments, the workpiece further includes an isolation feature disposed over the substrate and adjacent to the fin-shaped structure, and a bottom surface of the trench is below a top surface of the isolation feature. In some embodiments, filling the trench with the dielectric layer and the polycrystalline semiconductor material includes conformally depositing the dielectric layer in the trench and over a top surface of the dummy gate structure, and filling the trench with the polycrystalline semiconductor material. In some embodiments, forming the trench includes forming a hard mask layer over the dummy gate structure, patterning the hard mask layer to form an opening in the hard mask layer, and etching the dummy gate structure and the fin-shaped structure using the patterned hard mask layer as an etch mask.

In yet another exemplary aspect, the present disclosure is directed to a semiconductor structure. The semiconductor structure includes a substrate, an active region disposed over the substrate and including a channel region and a source/drain region, a gate structure disposed over the channel region of the active region and extending lengthwise along a first direction, a gate spacer disposed along a sidewall of the gate structure, and a source/drain feature disposed over the source/drain region of the active region. The channel region includes two sub-regions horizontally spaced apart along the first direction by the gate structure.

In some embodiments, the two sub-regions each have a first width along the first direction and the two sub-regions are spaced apart from each other by a first distance, and a first ratio of the first width to the first distance is about 1 to about 10. In some embodiments, the active region is a first active region, the gate structure is a first gate structure, and the channel region is a first channel region, and the semiconductor structure further includes a second active region and a third active region disposed over the substrate, a second gate structure extending lengthwise along the first direction and disposed over a second channel region of the second active region and a third channel region of the third active region, a fourth active region and a fifth active region disposed over the substrate, and a third gate structure extending lengthwise along the first direction and disposed over a fourth channel region of the fourth active region and a fifth channel region of the fifth active region. The second channel region and the third channel region each have a second width along the first direction and are spaced apart from each other by a second distance, the fourth channel region and the fifth channel region each have a third width along the first direction are spaced apart from each other by a third distance, and a second ratio of the second width to the second distance and a third ratio of the third width to the third distance are different from the first ratio. In some embodiments, the gate structure has a first portion disposed above the two sub-regions and a second portion disposed between the two sub-regions, the second portion of the gate structure is in direct contact with a top surface of a portion of the channel region between the two sub-regions, the first portion has a first width along a second direction perpendicular to the first direction, and the second portion has a second width along the second direction and greater than the first width. In some embodiments, the source/drain feature includes a first epitaxial layer disposed over the source/drain region and a second epitaxial layer disposed over the first epitaxial layer, the first epitaxial layer includes a dopant at a first concentration, and the second epitaxial layer includes the dopant at a second concentration greater than the first concentration. In some embodiments, the second epitaxial layer includes a first portion disposed over a top surface of the first epitaxial layer and a second portion disposed along a sidewall of the first epitaxial layer, the first portion has a first thickness and the second portion has a second thickness, a ratio of the first thickness to the second thickness is equal to or greater than about 2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece including:
a fin-shaped structure including a fin base and a stack of semiconductor layers over the fin base, wherein the stack of semiconductor layers includes channel layers interleaving with sacrificial layers,
a dummy gate structure disposed over the stack of semiconductor layers, and
a source/drain feature connected to the channel layers of the stack of semiconductor layers and disposed on a side of the dummy gate structure;
forming a trench in the dummy gate structure and the fin-shaped structure;
depositing a dielectric layer in the trench;
depositing a polycrystalline semiconductor material over the dielectric layer;
performing a planarization process to the workpiece; and
replacing the dielectric layer, the polycrystalline semiconductor material, the dummy gate structure, and the sacrificial layers with a metal gate structure.

2. The method of claim 1,
wherein the dummy gate structure extends lengthwise along a direction,
wherein the trench cuts a top portion of the fin-shaped structure into two segments,
wherein the trench has a first width of about 5 nm to about 20 nm along the direction, and
wherein each of the two segments has a second width of about 5 nm to about 50 nm along the direction.

3. The method of claim 1, wherein forming the trench includes:
forming a hard mask over the dummy gate structure,
patterning the hard mask to form an opening in the hard mask, and
etching the dummy gate structure and the fin-shaped structure using the patterned hard mask as an etch mask to form the trench.

4. The method of claim 1, wherein the trench extends through the stack of semiconductor layers and extends into the fin base.

5. The method of claim 1, wherein depositing the dielectric layer includes depositing the dielectric layer on a bottom surface and sidewalls of the trench and a top surface of the dummy gate structure.

6. The method of claim 5, wherein performing the planarization process includes removing the dielectric layer on the top surface of the dummy gate structure.

7. The method of claim 1, wherein the source/drain feature includes a first epitaxial layer disposed over the fin base and a second epitaxial layer disposed over the first epitaxial layer,
wherein the second epitaxial layer has a first portion disposed over a top surface of the first epitaxial layer and a second portion disposed along a sidewall of the first epitaxial layer, and
wherein the first portion has a first thickness, and the second portion has a second thickness smaller than the first thickness.

8. The method of claim 7, further comprising:
forming a silicide layer on the second epitaxial layer, and
forming a source/drain contact over the silicide layer.

9. A method, comprising:
providing a workpiece including a substrate and a fin-shaped structure protruding from the substrate, wherein the fin-shaped structure extends lengthwise along a first direction;
forming a dummy gate structure over the fin-shaped structure and extending lengthwise along a second direction perpendicular to the first direction;
forming a gate spacer along a sidewall of the dummy gate structure;
forming a source/drain trench in the fin-shaped structure and adjacent to the gate spacer;
forming a source/drain feature in the source/drain trench;
forming a trench in the dummy gate structure and the fin-shaped structure;
filling the trench with a dielectric layer and a polycrystalline semiconductor material;
performing a planarization process to the workpiece; and
replacing the dielectric layer, the polycrystalline semiconductor material, and the dummy gate structure with a metal gate structure.

10. The method of claim 9, wherein forming the source/drain feature in the source/drain trench includes:
forming a first epitaxial layer in the source/drain trench, and
forming a second epitaxial layer over the first epitaxial layer,
wherein the second epitaxial layer has a first portion over a top surface of the first epitaxial layer and a second portion along a sidewall of the first epitaxial layer,
wherein the first portion has a first thickness, and the second portion has a second thickness less than the first thickness.

11. The method of claim 9, wherein forming the trench removes a portion of the gate spacer, the dummy gate structure, and the fin-shaped structure.

12. The method of claim 9, wherein the workpiece further includes an isolation feature disposed over the substrate and adjacent to the fin-shaped structure,
wherein a bottom surface of the trench is below a top surface of the isolation feature.

13. The method of claim 9, wherein filling the trench with the dielectric layer and the polycrystalline semiconductor material includes:
conformally depositing the dielectric layer in the trench and over a top surface of the dummy gate structure, and
filling the trench with the polycrystalline semiconductor material.

14. The method of claim 9, wherein forming the trench includes:
forming a hard mask layer over the dummy gate structure,
patterning the hard mask layer to form an opening in the hard mask layer, and
etching the dummy gate structure and the fin-shaped structure using the patterned hard mask layer as an etch mask.

15. A semiconductor structure, comprising:
a substrate;
an active region disposed over the substrate and including a channel region and a source/drain region;
a gate structure disposed over the channel region of the active region and extending lengthwise along a first direction;
a gate spacer disposed along a sidewall of the gate structure; and
a source/drain feature disposed over the source/drain region of the active region,
wherein the channel region includes two sub-regions horizontally spaced apart along the first direction by the gate structure.

16. The semiconductor structure of claim 15, wherein the two sub-regions each have a first width along the first direction and the two sub-regions are spaced apart from each other by a first distance,
wherein a first ratio of the first width to the first distance is about 1 to about 10.

17. The semiconductor structure of claim 16, wherein the active region is a first active region, the gate structure is a first gate structure, and the channel region is a first channel region; and
wherein the semiconductor structure further comprises:
a second active region and a third active region disposed over the substrate,
a second gate structure extending lengthwise along the first direction and disposed over a second channel region of the second active region and a third channel region of the third active region,
a fourth active region and a fifth active region disposed over the substrate, and
a third gate structure extending lengthwise along the first direction and disposed over a fourth channel region of the fourth active region and a fifth channel region of the fifth active region,
wherein the second channel region and the third channel region each have a second width along the first direction and are spaced apart from each other by a second distance,
wherein the fourth channel region and the fifth channel region each have a third width along the first direction are spaced apart from each other by a third distance, and
wherein a second ratio of the second width to the second distance and a third ratio of the third width to the third distance are different from the first ratio.

18. The semiconductor structure of claim 15, wherein the gate structure has a first portion disposed above the two sub-regions and a second portion disposed between the two sub-regions,
wherein the second portion of the gate structure is in direct contact with a top surface of a portion of the channel region between the two sub-regions,
wherein the first portion has a first width along a second direction perpendicular to the first direction, and
wherein the second portion has a second width along the second direction and greater than the first width.

19. The semiconductor structure of claim 15, wherein the source/drain feature includes a first epitaxial layer disposed over the source/drain region and a second epitaxial layer disposed over the first epitaxial layer,
wherein the first epitaxial layer includes a dopant at a first concentration, and
wherein the second epitaxial layer includes the dopant at a second concentration greater than the first concentration.

20. The semiconductor structure of claim 19, wherein the second epitaxial layer includes a first portion disposed over a top surface of the first epitaxial layer and a second portion disposed along a sidewall of the first epitaxial layer,
wherein the first portion has a first thickness and the second portion has a second thickness,
wherein a ratio of the first thickness to the second thickness is equal to or greater than about 2.
